(19) United States
(12) Patent Application Publication
(10) Pub. No.: US 2022/0209166 A1
(43) Pub. Date: Jun. 30, 2022

(54) LIGHT-EMITTING ELEMENT AND DISPLAY DEVICE

(71) Applicant: SHARP KABUSHIKI KAISHA, Sakai City, Osaka (JP)

(72) Inventor: YOSHIHIRO UETA, Sakai City, Osaka (JP)

(21) Appl. No.: 17/602,489

(22) PCT Filed: Apr. 11, 2019
(86) PCT No.: PCT/JP2019/015794

§ 371 Date: Oct. 8, 2021

(51) Int. Cl. H01L 51/52

(52) U.S. Cl. CPC H01L 51/524; H01L 51/5221; H01L 51/5206

(57) ABSTRACT

A light-emitting element includes a first electrode, a light-emitting layer, a first DLC layer formed from diamond-like carbon, a second electrode, and a second DLC layer formed from DLC, wherein the first electrode, the light-emitting layer, the first DLC layer, the second electrode, and the second DLC layer are layered in this order.

### TECHNICAL FIELD

The disclosure relates to a light-emitting element and a display device.

### BACKGROUND ART

For example, PTL 1 discloses a light-emitting element including alight-emitting layer between a first electrode and a semiconductor layer formed from, for example, diamond-like carbon, the semiconductor layer including an edge portion electrically connected to a second electrode.

### CITATION LIST

### Patent Literature

PTL 1: WO 00/67531

### SUMMARY

### Technical Problem

In light-emitting element described above, the diamond-like carbon is merely exemplified as a material in the semiconductor layer.

An object of an aspect of the disclosure s to provide a light-emitting element with improved reliability by providing a diamond-like carbon layer above the second electrode compared to a case where the diamond-like carbon layer is not provided above the second electrode.

### Solution to Problem

A light-emitting element according to an aspect of the disclosure includes a first electrode, a light-emitting layer, a first DLC layer formed from diamond-like carbon (DLC), a second electrode, and a second DLC layer formed from DLC, the first electrode, the light-emitting layer, the first DLC layer, the second electrode, and the second DLC layer being layered in this order.

### BRIEF DESCRIPTION OF DRAWINGS

FIG. 1 is a cross-sectional view illustrating a configuration example of a light-emitting element according to a first embodiment.

FIG. 2 is a diagram illustrating a configuration example of a display device including the light-emitting element in FIG. 1.

FIG. 3 is a diagram showing reliability of light-emitting elements according to Example 1, Comparative Example 1, and Comparative Example 2.

FIGS. 4(a) to 4(c) are diagrams illustrating light distribution properties of light-emitting elements according to Example 1, Comparative Example 1, and Comparative Example 3, respectively.

FIG. 5 is a cross-sectional view illustrating a configuration example of a light-emitting element according to the second embodiment.

### DESCRIPTION OF EMBODIMENTS

With reference to the drawings, embodiments of the disclosure will be described. below. Note that, in the drawings, identical or equivalent elements are given an identical reference sign, and redundant descriptions thereof may be omitted.

### First Embodiment

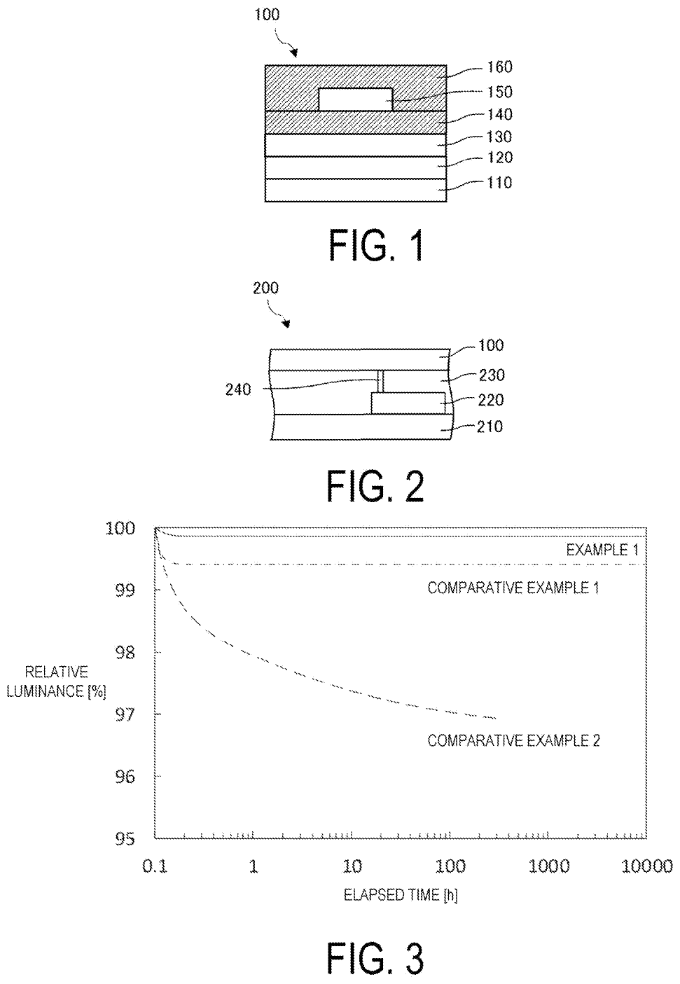

FIG. 1 is a schematic cross-sectional view of a light-emitting element 100 according to the present embodiment.

As illustrated in FIG. 1, the light-emitting element 100 according to the present embodiment includes, for example, a positive electrode (first electrode) 110, a hole transport layer (charge transport layer) 120, a light-emitting layer 130, a first DLC layer (electron transport layer) 140, a negative electrode (second electrode) 150, and a second DLC layer (sealing layer) 160. These layers are layered in order from the lowest layer, the positive electrode 110, the hole transport layer 120, the light-emitting layer 130, the first DLC layer (electron transport layer) 140, the negative electrode (second electrode) 150, and the second DLC layer (sealing layer) 160. Note that in the present embodiment, a direction from the light-emitting layer 130 of the light-emitting element 100 to the negative electrode (second electrode) 150 is described as “an upward direction”, and a direction from the light-emitting layer 130 of the light-emitting element 100 to the positive electrode (first electrode) 110 is described as “a downward direction”.

The positive electrode (first electrode) 110 includes, for example, a conductive material and is electrically connected to the hole transport layer 120 formed above the positive electrode 110. As the positive electrode 110, for example, Al, Cu, Au, Ag, Mg, or the like alone or an alloy thereof, or an oxide such as ITO, IZO, ZnO, AZO, BZO, or FTO is used. The first electrode 110 can be formed by, for example, sputtering. Note that when a light extraction direction in the light-emitting element 100 is in the downward direction, the positive electrode 110 is preferably a transparent electrode. The positive electrode 110 being a transparent electrode can transmit light emitted by the light-emitting layer 130, and thus a decrease in light extraction efficiency in the light-emitting element 100 can be suppressed. Conversely, when the light extraction direction in the light-emitting element 100 is in the upward direction, the positive electrode 110 is preferably formed from a material having a high visible light reflectivity. Thus, the light emitted by the light-emitting layer 130 can be reflected in the upward direction, and thus the light extraction efficiency in the light-emitting element 100 can be improved.

The hole transport layer 120 is, for example, a layer that transports positive holes generated by the positive electrode 110 to the light-emitting layer 130. As the hole transport layer 120, for example, a conductive organic compound, such as poly[(9,9-dioctylfluorenyl-2,7-diyl)-co-(4,4′-(N-(4-sec-butylphenyl))diphenylamine)] (TFB) or polyvinyl carbazole (PVK); or a metal oxide such as NiO, Cr₂O₃, MgO, MgZnO, LaNiO₃, MoO₃, and WO₃ can be used. The hole transport layer 120 can be formed by a commonly used film formation method, for example, such as vacuum vapor deposition or sputtering, or application of a colloid solution in which nanoparticles of each material are dispersed in a solvent. The hole transport layer 120 may also have a hole injection layer provided between the hole transport layer 120 and the first electrode 110. As the hole injection layer, for example, polyethylenedioxythiophene:polystyrenesulfonic acid (PEDOT:PSS) can be used. The hole injection layer can be formed, for example, by a coating method.

The light-emitting layer 130 emits light having a predetermined wavelength range by, for example, a voltage being applied between the positive electrode (first electrode) 110 and the negative electrode (second electrode) 150. Examples of the light-emitting layer 130 include, for example, a quantum dot layer including quantum dots, an organic light-emitting layer formed from organic luminescent body, and the like.

For example, the light-emitting layer 130, when the light-emitting layer 130 being a quantum dot layer, can be formed by a spin coating method, an ink-jet method, or the like, using a colloid solution in which quantum dots are dispersed in an organic solvent such as hexane or toluene. The quantum dot described above is formed from, for example, a core and a shell covering the periphery thereof. Further, a surface of a shell that forms a quantum dot is preferably bonded to a ligand formed from an organic compound. This ligand allows dangling hands, defects, and the like that present on the shell surface and that can be a non-emitting recombination center to be deactivated, and the dispersibility of the quantum dots with respect to the solvent of the colloid solution to be improved. Note that a film thickness of the quantum dot layer is preferably from 2 nm to 50 nm. Further, an example of the quantum dot may include a Cd-based semiconductor nanoparticle having a core/shell structure including CdSe in the core and ZnS in the shell. In addition, the quantum dot may have CdSe/CdS, InP/ZnS, ZnSe/ZnS, CIGS/ZnS, or the like as the core/shell structure. Furthermore, the quantum dot may be a quantum dot formed from Si or C, or a nitride-based compound.

The first DLC layer 140 is a layer formed from diamond-like carbon (DLC). The first DLC layer 140 according to the present embodiment is an electron transport layer (charge transport layer) that transports electrons from the negative electrode 150 to the light-emitting layer 130. The first DLC layer 140 can be formed by, for example, plasma CVD. The first DLC layer 140 is preferably a semiconductor, for example, an n-type DLC layer, which is an n-type semiconductor, in order to provide an electron transport capability. The n-type DLC layer preferably includes, for example, as an impurity, N, P, As, Sb, or Bi, which is a group V element, alone or in a mixture of two or more types. In addition, for concentrations of these impurities, a concentration of each element alone or a mixed concentration is preferably 10¹⁶ cm⁻³ or more and 10²⁰ cm⁻³ or less. This concentration range allows an electron density in the first DLC layer (electron transport layer) 140 to be increased.

A film thickness of the first DLC layer 140 is preferably 2 nm or more and 20 nm or less. The film thickness of the first DLC layer 140 being 2 nm or more allows the light-emitting layer 130 to be covered without any gap, and the light-emitting layer 130 can be better protected. In particular, high gas barrier properties of DLC effectively prevent oxidation, sulfurization, and the like of the positive electrode 110 and the light-emitting layer 130 provided below the first DLC layer 140. For example, when the film thickness of the first DLC layer 140 is less than 2 nm, the first DLC layer 140 is formed in island shapes, and the effect of protecting the light-emitting layer 130 may be reduced. On the other hand, for example, when the film thickness is greater than 20 nm, the light emitted by the light-emitting layer 130 is absorbed, and the light extraction efficiency in the light-emitting element 100 may decrease.

Also, the n-type DLC forming the first DLC layer 140 is preferably amorphous carbon. This more suppresses diffusion of oxygen and water into the lower layer of the first DLC layer 140 and allows barrier properties to be improved.

Further, the n-type DLC forming the first DLC layer 140 preferably includes hydrogen. Furthermore, hydrogen concentration in the first DLC layer 140 is more preferably 5% or less with respect to that of carbon in the first DLC layer 140. This suppresses diffusion of oxygen into the lower layer of the first DLC layer 140 and allows barrier properties to be improved, because the hydrogen contained in the first DLC layer 140 trap oxygen, among others, for example. Also, when the hydrogen concentration is greater than 5%, the hydrogen may cause the first DLC layer 140 to expand. When the first DLC layer 140 expands in this way, peeling may occur at an interface between the first DLC layer 140 and the other layer. As a result of this peeling, in turn, the first DLC layer 140 may cause a decrease in electron transport capability and a decrease in gas barrier capability.

The negative electrode (second electrode) 150 includes, for example, a conductive material and is electrically connected to the first DLC layer 140. As the negative electrode 150, for example, Al, Cu, Au, Ag, Mg, or the like alone or an alloy thereof, or an oxide such as ITO, IZO, ZnO, AZO, BZO, or FTO is used. The negative electrode 150 can be formed by, for example, sputtering. Note that when the light extraction direction in the light-emitting element 100 is in the upward direction, the negative electrode 150 is preferably a transparent electrode. The negative electrode being a transparent electrode can transmit light emitted by the light-emitting layer 130, and thus a decrease in light extraction efficiency in the light-emitting element 100 can be suppressed. Conversely, when the light extraction direction in the light-emitting element 100 is in the downward direction, the negative electrode 150 is preferably formed from a material having a high visible light reflectivity. Thus, the light emitted by the light-emitting layer 130 can be reflected in the downward direction, and thus the light extraction efficiency in the light-emitting element 100 can be improved.

The second DLC layer 160 is formed from diamond-like carbon (DLC). The second DLC layer 160 seals, for example, at least the negative electrode 150. Thus, the second DLC layer 160 can also be referred to as a sealing layer. The second DLC layer 160 can be formed by, for example, plasma CVD. A film thickness of the second DLC layer 160 is preferably 2 nm or more and 20 nm or less. The film thickness of the second DLC layer 160 being 2 nm or more allows the second DLC layer to be formed, instead of in island shapes, in a continuous film, which can cover the negative electrode 150 with less gaps, when formed by plasma CVD, for example, and deterioration caused by oxidation, sulfide, or the like of at least the negative electrode 150 can be suppressed due to high gas barrier properties of DLC. Further, the high gas barrier properties of DLC suppress deterioration from oxidation, sulfurization, and the like of the positive electrode 110, the light-emitting layer 130, and the like provided below the negative electrode 150. Also, the film thickness of the second DLC layer 160 being 20 nm or less suppresses absorption of light emitted by the light-emitting layer 130 and suppresses a decrease in light extraction efficiency in the light-emitting element 100.

Further, the DLC forming the second DLC layer 160 preferably includes hydrogen. Furthermore, the hydrogen concentration in the second DLC layer 160 is more preferably 5% or less with respect to that of carbon. This suppresses diffusion of oxygen into the lower layer of the second DLC layer 160 and allows barrier properties to be improved, because the hydrogen contained in the second. DLC layer 160 is considered to trap oxygen, among others, for example. Also, when the hydrogen concentration is greater than 5%, the hydrogen may cause the second. DLC layer 160 to expand. When the second DLC layer 160 expands in this way, peeling may occur at an interface between the second DLC layer 160 and the other layer, As a result of this peeling, in turn, the second DLC layer 160 may cause a decrease in sealing capability and a decrease in gas barrier capability.

Note that the negative electrode 150 is preferably formed to be embedded between the second DLC layer 160 and the first DLC layer 140. Additionally, the negative electrode 150 is preferably provided to be covered with the second DLC layer 160 from above. In particular, the negative electrode 150 is preferably completely covered with the second DLC layer 160. This prevents the negative electrode 150 from deteriorating.

Note that a method of forming the second electrode 150 to be embedded between the sealing layer 160 formed from DLC and the electron transport layer 140 formed from DLC is as follows, for example.

The first DLC layer 140 is formed on the light-emitting layer 130 by, for example, plasma CVD. A region of the negative electrode (second electrode) 150 then opens on the first DLC layer 140 by lithography, for example, to form a resist mask with the first DLC layer 140 exposed to the opening. Next, the negative electrode 150 is formed by vacuum vapor deposition or sputtering. Then, the resist mask is removed by lift-off. This allows the negative electrode 150 electrically connected to the first DLC layer 140 to be formed. Subsequently, by performing film formation of the second DLC layer 160 by plasma CVD again from above the negative electrode 150. the negative electrode 150 can be embedded between the first DLC layer 140 and the second DLC layer 160.

In addition, the light extraction direction in the light-emitting element 100 according to the present embodiment is not particularly limited thereto, but is preferably the upward direction. A thickness obtained by adding the first DLC layer (electron transport layer) 140, the negative electrode (second electrode) 150, and the second DLC layer (sealing layer) 160 which are above the light-emitting layer 130 is preferably 70 nm or more and 90 nm or less. This allows the light from the light-emitting layer 130 to be efficiently emitted from the second DLC layer 160 into the atmosphere (in the upward direction of FIG. 1). In the present embodiment, DLC is used for the first DLC layer 140 and the second DLC layer 160, and the film thicknesses of the first DLC layer 140 and the second DLC layer 140 can be made thin as described above based on the level of the sealing capability of the DLC. This allows the total film thickness of the three layers of the first DLC layer 140, the negative electrode 150, and the second DLC layer 160 to be reduced. In other words, as described above, the total film thickness of the three layers can be made on the order of 1/10 of the visible light, such as 70 nm or more and 90 nm or less, as described above, and thus the three layers can be considered as a unitary film, and a value obtained by averaging refractive indices of the respective layers can be considered to be a refractive index of the three layers. Thus, in the three layers described above, the extraction efficiency of the light emitted from the light-emitting element 100 to the atmosphere (that is, the light extracted from the sealing layer 160) is dependent on the refractive index of the three layers. Furthermore, the greater the total internal reflection angle at the light extraction surface of the light-emitting element 100, the more light is transmitted to the light extraction surface side, and thus the light emission efficiency is improved.

For example, when a light-emitting element has a first configuration with the first DLC layer of 10 nm, the second electrode (Mg—Ag layer) of 50 nm, and the second DLC layer of 10 nm, the total internal reflection angle associated with light emitted from the three layers to the atmosphere was 71°. On the other hand, when a light-emitting element has a second configuration with the first DLC layer of 10 nm and the second electrode (Mg—Ag layer) of 50 nm, the total internal reflection angle associated with light emitted from the two layers to the atmosphere was 65°. In this way, even when the second DLC layer is formed, the thickness of the three layers is adjusted as the light-emitting element of the first configuration described above, and thus the light incident at the total internal reflection angle equivalent to the light-emitting element of the second configuration can also be extracted in the atmospheric direction. Note that the average refractive index of three layers formed from the first DLC layer, the second electrode, and the second DLC layer is preferably from 1.3 to 1.5, and by setting the average refractive index in this range, the light emitted from the light-emitting layer can be efficiently emitted in the direction of the second DLC layer. In a third light-emitting element in which a glass having a thickness of 500 μm is additionally used in the light-emitting element having the second configuration described above as a glass sealing layer having a known structure, the glass sealing layer covering the second electrode (for example, Mg—Ag) from above, the third light-emitting element sealed by bonding with TFT array substrate using an epoxy resin or a UV curable resin, or a dimethyl silicone based resin, the total internal reflection angle is 48°, and light incident on the glass sealing layer at a greater angle is totally internally reflected and cannot be extracted to the atmosphere.

In particular, in a case where the light-emitting layer 130 is a quantum dot layer, an intermediate layer may be added to an interface between the hole transport layer 120 and the light-emitting layer 130. For manufacturing the intermediate layer, the same approach as that of the hole transport layer 120 can be used. Here, the intermediate layer acts to suppress the positive hole, from the hole transport layer 120, injected into the light-emitting layer 130, which is a quantum dot layer, from being caught by dangling bonds, defects, and the like present at the interface between the hole transport layer 120 and a quantum dot layer 7.

Here, a configuration example of a display device 200 including the light-emitting element 100 will be described. As illustrated in FIG. 2, in the display device 200, a TFT element 220 including a thin film transistor (TFT) is provided on a substrate 210. Furthermore, an insulating layer 230 is provided on the substrate 210 to cover the TFT element 220. The light-emitting element 100 is provided on the insulating layer 230. The light-emitting element 100 is electrically connected to the ITT element 220 via a contact hole 240 or the like provided in the insulating layer 230. Note that a protective layer may be further provided on the light-emitting element 100.

Examples of the substrate 210 include, for example, a flexible resin substrate, a rigid glass substrate, and the like.

The insulating layer 230 is formed of, for example, an insulating material such as polyimide. The insulating layer 230 may be formed by layering a plurality of layers, for example.

Examples of the TFT element 220 includes, for example, a top gate type, a bottom gate type, a double gate type, and the like, but is not particularly limited thereto.

### EXAMPLE 1

In the present example, an light-emitting element 100 is prepared by layering: an ITO layer of 30 nm as the positive electrode (first electrode) 110; a layered body having layered a layer formed from PEDOT:PSS of 20 nm and a layer formed from TFB of 40 nm as the hole transport layer 120; a quantum dot layer of 30 nm including a CdZnSe core/ZnS shell as a quantum dot as the light-emitting layer 130; an n-type DLC layer containing Sb (antimony) as an impurity of 10 nm as the first DIX layer (electron transport layer) 140; an Al layer of 50 nm as the negative electrode (second electrode); and a DLC layer of 10 nm layer as the second DLC layer (sealing layer) 160.

### COMPARATIVE EXAMPLE 1

As the light-emitting element of Comparative Example 1, the light-emitting element that is not provided with the second DLC layer (sealing layer) in the light-emitting element of Example 1 was prepared.

### COMPARATIVE EXAMPLE 2

As the light-emitting element of Comparative Example 2, the light-emitting element that is not provided with the second DLC layer (sealing layer) in the light-emitting element of Example 1 with the electron transport layer replaced with a ZnO layer of 40 nm was prepared.

### COMPARATIVE EXAMPLE 3

As the light-emitting element of Comparative Example 3, the light-emitting element having performed common thin film encapsulation (TFE) sealing in the light-emitting element of Comparative Example 1 was prepared. In the TFE sealing, a sealing layer is obtained in which, for example, an organic layer, such as PMMA, being formed to approximately 200 nm and an inorganic layer, such as Al₃O₃, being formed to approximately 500 nm are layered as one unit, and the unit is repeatedly layered approximately three cycles.

### Evaluation

Light distribution properties were evaluated.

### Evaluation of Reliability

Evaluation of reliability was performed on the light-emitting elements of Example 1, Comparative Example 1, and Comparative Example 2. The evaluation of reliability of the light-emitting elements was performed by measuring changes in luminance with respect to elapsed time with initial luminance of 2000 cd/m² and driving with constant voltage and current in a constant temperature reservoir with a temperature of 80° C. and a humidity of 80%. The evaluation results are shown in FIG. 3. Note that in FIG. 3, the results of Example 1 is indicated by solid line, the result of Comparative Example 1 is indicated by dot-dash line, and the result of Comparative Example 2 is indicated by dashed line.

As shown in FIG. 3, the light-emitting element of Example 1 maintained substantially constant luminance after a slight (approximately 0.3%) luminance reduction at the beginning of the reliability test, and the luminance reduction was not seen even after driving operation for 1000 hours or longer.

In addition, the light-emitting element of Comparative Example 1 had a luminance reduction of approximately 0.6% at the beginning of the reliability test, and the luminance reduction after 1000 hours or more of the driving operation was approximately 8%. The luminance reduction at the beginning and after 1000 hours or longer are both greater than the reliability test results of Example 1, and thus, it is assumed to be a result of a difference in gas barrier properties, which appears to be involved in a long term luminance reduction, and in the contact of the electrode which is believed to be mainly related to the initial luminance reduction.

Furthermore, the light-emitting element of Comparative Example 2 exhibited a monotonic decrease over time after there was a large output reduction at the beginning of the reliability test. The relative luminance was then below 97% at the time of 300 hours. From these results, compared to the light-emitting element 100 of Example 1, that of Comparative Example 2 was found to be less reliable.

### Evaluation of Light Distribution Properties

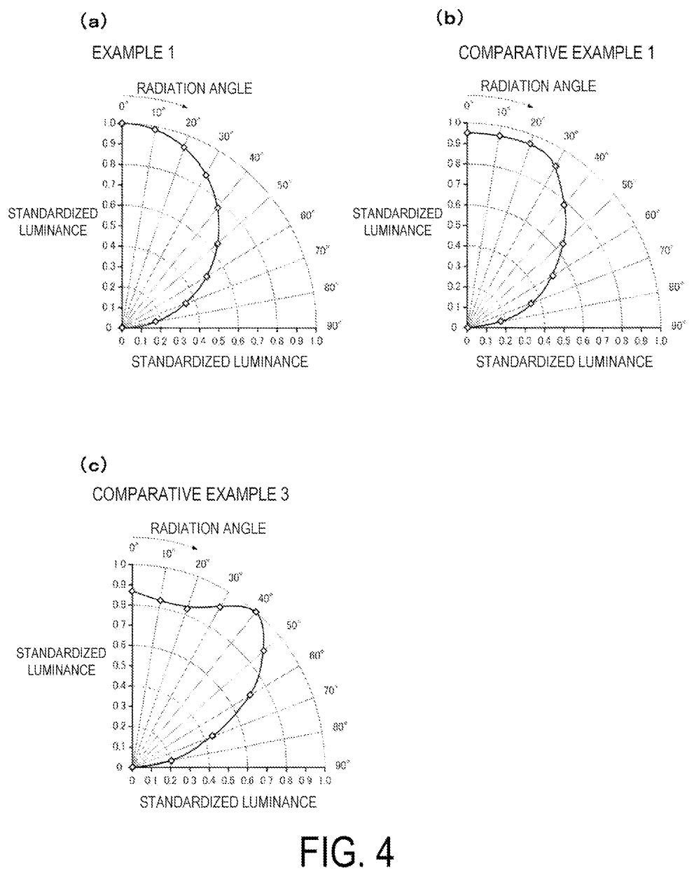

Evaluation of light distribution properties was performed on the light-emitting elements of Example 1, Comparative Example 2, and Comparative Example 3. The evaluation of light distribution properties of the light-emitting element was performed by measuring luminance light distribution properties of the actual light-emitting element. The results are shown in FIG. 4. FIG. 4(a) shows the light distribution properties of the light-emitting element of Example 1, and FIG. 4(b) shows the light distribution properties of the light-emitting element of Comparative Example 1. FIG. 4(c) shows the light distribution properties of the light-emitting element of Comparative Example 3. As shown in FIG. 4(a), the light distribution properties of the light-emitting element of Example 1 were close to ideal Lambertian. Also, as shown in FIG. 4(b), the light distribution properties of the light-emitting element of Comparative Example 1 were close to ideal Lambertian. These results revealed that even when the second DLC layer was formed as in Example 1, by making the film thickness of the three layers thin, the light distribution properties are not affected. Furthermore, as shown in FIG. 4(c), the light distribution properties of the light-emitting element of Comparative Example 3 were significantly different from the Lambertian. Furthermore, the result showed a large change in luminance, particularly in the range from 0° to 40°. This is presumably influenced by the layered structure and thickness of the TFE sealing layer.

According to the light-emitting element of the present embodiment, the second electrode is formed between the first DLC layer and the second DLC layer, and thus deterioration of the second electrode is particularly prevented. Furthermore, deterioration of the light-emitting layer, the hole transport layer, the first electrode, and the like provided below the first DLC layer and the second DLC layer can be prevented.

### Second Embodiment

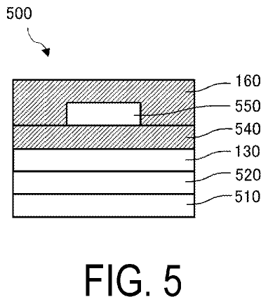

FIG. 5 is a schematic cross-sectional view of a light-emitting element 500 according to the present embodiment. Note that, hereinafter, description of a similar configuration with the first embodiment will be omitted. The present embodiment is a configuration in which, in the first embodiment, the positive electrode and the negative electrode are switched, and accordingly the electron transport layer and the hole transport layer are switched.

As illustrated in FIG. 5, the light-emitting element 500 according to the present embodiment includes, for example, a negative electrode (first electrode) 510, an electron transport layer (charge transport layer) 520, a light-emitting layer 130, a first DLC layer (hole transport layer) 540, a positive electrode (second electrode) 550, and a second DLC layer (sealing layer) 160. These layers are layered in order from the lowest layer, the negative electrode (first electrode) 510, the electron transport layer 520, the light-emitting layer 130, the first DLC layer (hole transport layer) 540, the positive electrode (second electrode) 550, and the second DLC layer (sealing layer) 160. Note that in the present embodiment, a direction from the light-emitting layer 130 of the light-emitting element 500 to the positive electrode (second electrode) 550 is described as “an upward direction”, and a direction from the light-emitting layer 130 of the light-emitting element 500 to the negative electrode (first electrode) 510 is described as “a downward direction”. Additionally, in the present embodiment, the negative electrode 510 and the positive electrode 550 are each configured in the similar manner to the positive electrode 110 and the negative electrode 150 of the first embodiment.

In the present embodiment, the electron transport layer 520 transports electrons generated at the negative electrode 510 to the light-emitting layer 130. The electron transport layer 520 is formed of a metal oxide film, for example, such as TiO₂, ZnO, ZAO (Al-doped ZnO), ZnMgO, ITO, and IGZO (InGaZnOₓ: trade name). However, the electron transport layer 520 may be formed of a conductive polymer such as Alq₃, BCP, t-Bu-PBD, and the like.

In the present embodiment, the first DLC layer 540 is a layer formed from DLC. The first DLC layer 540 according to the present embodiment is a hole transport layer (charge transport layer) that transports holes from the positive electrode 550 to the light-emitting layer 130. The first DLC layer 540 can be formed by, for example, plasma CND. The first DLC layer 540 is preferably a semiconductor, for example, a p-type DLC layer, which is a p-type semiconductor, in order to provide a hole transport capability. The p-type DLC layer preferably includes, for example, as an impurity, at least one element selected from the group consisting of B, Al, Ga, and In. In addition, for concentrations of these impurities, a concentration of each element alone or a mixed concentration is preferably 10¹⁶ cm⁻³ or more and 10²⁰ cm⁻³ or less. This concentration range allows a hole density in the first DLC layer (hole transport layer) 540 to be increased.

A film thickness of the first DLC layer 540 is preferably 2 nm or more and 20 nm or less. The film thickness of the first DLC layer 540 being 2 nm or more allows the light-emitting layer 130 to be covered with less gaps, and the light-emitting layer 130 can be better protected. In particular, the high gas barrier properties of DLC effectively prevent oxidation, sulfurization, and the like of the negative electrode 510 and the light-emitting layer 130 provided below the first DLC layer 540. For example, when the film thickness of the first DLC layer 540 is 2 nm, the first DLC layer 540 is formed in island shapes, and the effect of protecting the light-emitting layer 130 may be reduced. On the other hand, for example, when the film thickness is greater than 20 nm, the light emitted by the light-emitting layer 130 is absorbed, and the light extraction efficiency in the light-emitting element 100 may decrease.

Also, the p-type DLC forming the first DLC layer 540 is preferably amorphous carbon. This more suppresses diffusion of oxygen and water into the lower layer of the first DLC layer 540 and allows barrier properties to be improved.

Further, the p-type DLC forming the first DLC layer 540 preferably includes hydrogen. Furthermore, the hydrogen concentration in the first DLC layer 540 is more preferably 5% or less with respect to that of carbon. This suppresses diffusion of oxygen into the lower layer of the first DLC layer 540 and allows barrier properties to be improved, because the hydrogen contained in the first DLC layer 540 trap oxygen, among others, for example. Also, when the hydrogen concentration is greater than 5%, the hydrogen may cause the first DLC layer 540 to expand. When the first DLC layer 540 expands in this way, peeling may occur at an interface between the first DLC layer 540 and the other layer. As a result of this peeling, in turn, the first DLC layer 540 may cause a decrease in positive hole transport capability and a decrease in gas barrier capability.

Also, as another embodiment of the hole transport layer of the present embodiment, a second hole transport layer that is provided between the first DLC layer 540 and the light-emitting layer 130 and that is formed from, for example, a conductive organic compound, such as poly[(9,9-dioctylfluorenyl-2,7-diyl)-co-(4,4′-(N-(4-sec-butylphenyl))diphenylamine)] (TFB) or polyvinyl carbazole (PVK) or a metal oxide such as NiO, Cr₂O₃, MgO, MgZnO, LaNiO₃, MoO₃, or WO₃ may be included. In this case, the first DLC layer 540 functions as a hole injection layer that injects holes generated at the second electrode 550 into the second hole transport layer.

Note that a method of manufacturing the first DLC layer 540, the positive electrode 550, and the second DLC layer 160 in the present embodiment is similar to that of the first DIX layer 140, the negative electrode 150, and the second DLC layer 160 in the first embodiment.

Reliability tests were performed on the light-emitting element of the second embodiment under similar conditions to that of the first embodiment. The light-emitting element of the second embodiment maintained substantially constant luminance after a slight (approximately 0.28%) luminance reduction at the beginning of the reliability test, and luminance reduction was not seen even after driving operation for 1000 hours or longer. The deterioration at the beginning of the test is presumed to be a deterioration associated with the contact of the electrode, as is the result of the first embodiment, and the difference in 0.02% from the first embodiment is due to variation in element characteristics, and is considered substantially equivalent to the reliability of the first embodiment.

Also, similar to the first embodiment, a light-emitting element is prepared by layering an Al layer of 50 nm as the negative electrode (first electrode) 510; a ZnO layer of nm as the electron transport layer 520; a quantum dot layer of 30 nm including a CdZnSe core/ZnS shell as a quantum dot as the light-emitting layer 130; a layered body having layered a TFB layer of 40 nm and a p-type DLC layer of 10 nm containing B (boron) as impurities as the hole transport layer 540, an ITO layer of 30 nm as the positive electrode (second electrode) 550, and a DLC layer of 10 nm as the second DLC layer (sealing layer). When evaluated, the prepared light-emitting element had high reliability similar to that of the first embodiment.

Furthermore, the light-emitting element 500 described above can form a display device by replacing the light-emitting element 100 in the display device illustrated in FIG. 2 with the light-emitting element 500.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A light-emitting element comprising:
a first electrode;
a light-emitting layer;
a first DLC layer formed from diamond-like carbon (DLC);
a second electrode; and
a second DLC layer formed from DLC,
wherein the first electrode, the light-emitting layer, the first DLC layer, the second electrode, and the second DLC layer are layered in this order.

2. The light-emitting element according to claim 1,
wherein the first DLC layer is a charge transport layer.

3. The light-emitting element according to claim 1,
wherein the second DLC layer is a sealing layer sealing the second electrode.

4. The light-emitting element according to claim 1,
wherein the second electrode is embedded between the first DLC layer and the second DLC layer.

5. The light-emitting element according to claim 1,
wherein light from the light-emitting layer is emitted outside from a side of the second electrode.

6. The light-emitting element according to claim 5,
wherein a film thickness from the first DLC layer to the second DLC layer is 70 nm or more and 90 nm or less.

7. The light-emitting element according to claim 3,
wherein the second electrode is in direct contact with the first DLC layer and the second DLC layer.

8. The light-emitting element according to claim 1,
wherein a thickness of the second DLC layer is 2 nm or more and 20 nm or less.

9. The light-emitting element according to claim 1,
wherein hydrogen concentration in DLC of the second DLC layer is 5% or less.

10. The light-emitting element according to claim 1,
wherein a thickness of the first DLC layer is 2 nm or more and 20 nm or less.

11. The light-emitting element according to claim 1,
wherein hydrogen concentration in DLC of the first DLC layer is 5% or less.

12. The light-emitting element according to claim 1,
wherein the first electrode is a positive electrode and the first DLC layer is an n-type DLC layer formed from an n-type semiconductor.

13. The light-emitting element according to claim 12,
wherein the n-type DLC layer comprises at least one element selected from the group consisting of N, P, As, Sb, and Bi at a concentration of 10¹⁶ cm⁻³ or more and 10²⁰ cm⁻³ or less.

14. The light-emitting element according to claim 1,
wherein the first electrode is a negative electrode and the first DLC layer is a p-type DLC layer formed from a p-type semiconductor.

15. The light-emitting element according to claim 14,
wherein the p-type DLC layer comprises at least one element selected from the group consisting of B, Al, Ga, and In at a concentration of 10¹⁶ cm⁻³ or more and 10²⁰ cm⁻³ or less.

16. A display device comprising the light-emitting element according to claim 1.
